(19) United States
(12) Patent Application Publication
(10) Pub. No.: US 2024/0332199 A1
(43) Pub. Date: Oct. 3, 2024

(54) PRINTED CIRCUIT BOARD

(71) Applicant: SAMSUNG ELECTRO-MECHANICS CO., LTD., Suwon-si (KR)

(72) Inventors: Chi Hyeon JEONG, Suwon-si (KR); Seong Hwan LEE, Suwon-si (KR); Hyun Sang KWAK, Suwon-si (KR); Min Cheol PARK, Suwon-si (KR); Sang Jong LEE, Suwon-si (KR)

(73) Assignee: SAMSUNG ELECTRO-MECHANICS CO., LTD., Suwon-si (KR)

(21) Appl. No.: 18/226,988

(22) Filed: Jul. 27, 2023

(30) Foreign Application Priority Data
Mar. 31, 2023 (KR) 10-2023-0042652

(51) Int. Cl. H01L 23/538; H01L 21/48

(52) U.S. Cl. CPC H01L 23/5385; H01L 21/4846; H01L 23/5386; H01L 24/13; H01L 24/16; H01L 25/0655; H01L 2224/13111; H01L 2224/13124; H01L 2224/13147; H01L 2224/16227; H01L 2924/014

(57) ABSTRACT

A printed circuit board includes a substrate having an upper surface at which a plurality of first pads are disposed, and an interconnect structure including an encapsulant, a plurality of second pads disposed at an upper surface of the encapsulant, and a plurality of metal wires disposed in the encapsulant and respectively connected to at least one of the plurality of second pads, the interconnect structure disposed on an upper side of the substrate. At least a portion of an upper surface of each of the plurality of first and second pads is exposed in an upward direction from the upper surface of each of the substrate and the encapsulant.

### CROSS-REFERENCE TO RELATED APPLICATION (S)

This application claims benefit of priority to Korean Patent Application No. 10-2023-0042652 filed on Mar. 31, 2023 in the Korean Intellectual Property Office, the disclosure of which is incorporated herein by reference in its entirety.

### TECHNICAL FIELD

The present disclosure relates to a printed circuit board, for example, a printed circuit board having an embedded interconnect structure for interconnecting a plurality of semiconductor chips.

As the number of CPU and GPU cores in server products rapidly increases, die split technology capable of effectively increasing the number of cores has become common. In addition, with an increase in demand for a package including a high bandwidth memory (HBM), technology for connecting a die to a die using a fine circuit line width has been required. In order to satisfy such a technical requirement, technology for embedding a silicon bridge, technology for using a silicon interposer, and the like, have been developed. However, there are limitations in commercialization due to price issues and complicated assembly processes. For example, in the technology for embedding a silicon bridge, when multiple dies are connected to each other, alignments of respective silicon bridges are different from each other, causing an alignment issue. Undulation occurs on a front surface of a substrate on which a die is mounted, and thus issues may arise in packaging yield. In addition, technology using a silicon interposer is expensive, and a process for manufacturing the same is complicated.

### SUMMARY

An aspect of the present disclosure provides a printed circuit board having an interconnect function that may be manufactured using a simple process.

Another aspect of the present disclosure provides a printed circuit board having an interconnect function that may be manufactured at low cost.

According to an aspect of the present disclosure, an interconnect structure for a die-to-die interconnect may be manufactured using a metal wire, and the interconnect structure may be disposed on an upper side of a substrate to provide a printed circuit board having an interconnect function.

For example, a printed circuit board according to an example may include a substrate having an upper surface at which a plurality of first pads are disposed, and an interconnect structure including an encapsulant, a plurality of second pads disposed at an upper surface of the encapsulant, and a plurality of metal wires disposed in the encapsulant and respectively connected to at least one of the plurality of second pads, the interconnect structure disposed on an upper side of the substrate. At least a portion of an upper surface of each of the plurality of first and second pads may be exposed in an upward direction from the upper surface of each of the substrate and the encapsulant.

For example, a printed circuit board according to an example may include a substrate, and an interconnect structure disposed at an outermost side of the substrate, the interconnect structure including a plurality of metal wires. At least one of the plurality of metal wires may include a signal line interconnecting a plurality of semiconductor chips.

According to example embodiments of the present disclosure, there may be provided a printed circuit board having an interconnect function that may be manufactured using a simple process.

According to example embodiments of the present disclosure, there may be provided a printed circuit board having an interconnect function that may be manufactured at low cost.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a schematic block diagram illustrating an example of an electronic device system;

FIG. 2 is a schematic perspective view illustrating an example of an electronic device;

FIG. 3 is a schematic cross-sectional view illustrating a case in which a BGA package is mounted on a main board of an electronic device;

FIG. 4 is a schematic cross-sectional view illustrating a case in which a silicon interposer package is mounted on a main board;

FIG. 5 is a schematic cross-sectional view illustrating a case in which an organic interposer package is mounted on a main board;

FIG. 6 is a schematic perspective view illustrating an example of an interconnect structure;

FIG. 7 is a schematic cross-sectional view illustrating an example of a printed circuit board;

FIG. 8 is a schematic cross-sectional view illustrating a modification of the printed circuit board of FIG. 7;

FIGS. 9A to 9G are schematic process diagrams illustrating an example of manufacturing the printed circuit board of FIGS. 7 and 8;

FIG. 10 is a schematic cross-sectional view illustrating another example of a printed circuit board;

FIG. 11 is a schematic cross-sectional view illustrating a modification of the printed circuit board of FIG. 10;

FIG. 12 is a schematic cross-sectional view illustrating another example of a printed circuit board;

FIG. 13 is a schematic cross-sectional view illustrating a modification of the printed circuit board of FIG. 12;

FIG. 14 is a schematic cross-sectional view illustrating another example of a printed circuit board;

FIG. 15 is a schematic cross-sectional view illustrating a modification of the printed circuit board of FIG. 14;

FIG. 16 is a schematic cross-sectional view illustrating another example of a printed circuit board;

FIG. 17 is a schematic cross-sectional view illustrating a modification of the printed circuit board of FIG. 16;

FIG. 18 is a schematic cross-sectional view illustrating another example of a printed circuit board; and

FIG. 19 is a schematic cross-sectional view illustrating a modification of the printed circuit board of FIG. 18.

### DETAILED DESCRIPTION

Hereinafter, the present disclosure will be described with reference to the accompanying drawings. The shapes and sizes of elements in the drawings may be exaggerated or reduced for clearer description.

### Electronic Device

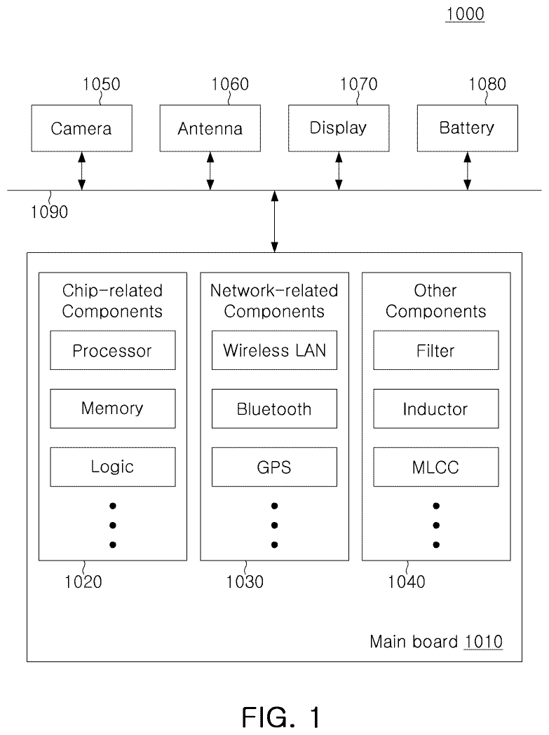

FIG. 1 is a schematic block diagram illustrating an example of an electronic device system.

Referring to FIG. 1, an electronic device 1000 may accommodate a mainboard 1010. The mainboard 1010 may include chip-related components 1020, network-related components 1030, other components 1040, or the like, physically or electrically connected thereto. Such components may be connected to other components to be described below to form various signal lines 1090.

The chip-related components 1020 may include memory chip such as a volatile memory (for example, a dynamic random access memory (DRAM)), a non-volatile memory (for example, a read only memory (ROM)), a flash memory, or the like, an application processor chip such as a central processor (for example, a central processing unit (CPU)), a graphics processor (for example, a graphics processing unit (GPU)), a digital signal processor, a cryptographic processor, a microprocessor, a microcontroller, or the like, and a logic chip such as an m analog-to-digital converter, an application-specific integrated circuit (ASIC), or the like, or the like. However, the chip-related components 1020 are not limited thereto, and may include other types of chip-related components. In addition, the chip-related components 1020 may be combined with each other. The chip-related components 1020 may be in the form of a package including the above-described chip or electronic component.

The network-related components 1030 may include protocols such as wireless fidelity (Wi-Fi) (Institute of Electrical And Electronics Engineers (IEEE) 802.11 family, or the like), worldwide interoperability for microwave access (WiMAX) (IEEE 802.16 family, or the like), IEEE 802.20, long term evolution (LTE), evolution data only (Ev-DO), high speed packet access+(HSPA+), high speed downlink packet access+(HSDPA+), high speed uplink packet access+(HSUPA+), enhanced data GSM environment (EDGE), global system for mobile communications (GSM), global positioning system (GPS), general packet radio service (GPRS), code division multiple access (CDMA), time division multiple access (TDMA), digital enhanced cordless telecommunications (DECT), Bluetooth®, 3G, 4G, and 5G protocols, and any other wireless and wired protocols, designated after the above-described protocols. However, the network-related components 1030 are not limited thereto, and may also include a variety of other wireless or wired standards or protocols. In addition, the network-related components 1030 may be combined with each other, together with the chip-related components 1020 described above.

Other components 1040 may include a high frequency inductor, a ferrite inductor, a power inductor, ferrite beads, a low temperature co-fired ceramic (LTCC), an electromagnetic interference (EMI) filter, a multilayer ceramic capacitor (MLCC), or the like. However, other components 1040 are not limited thereto, and may also include passive components used for various other purposes, or the like. In addition, other components 1040 may be combined with each other, together with the chip-related components 1020 or the network-related components 1030 described above.

Depending on a type of the electronic device 1000, the electronic device 1000 may include other components that may or may not be physically or electrically connected to the mainboard 1010. The other components may include, for example, a camera 1050, an antenna 1060, a display 1070, a battery 1080, and the like. However, the other components are limited thereto, and may be an audio codec, a video codec, a power amplifier, a compass, an accelerometer, a gyroscope, a speaker, a mass storage unit (for example, a hard disk drive), a compact disk (CD), a digital versatile disk (DVD), or the like. In addition, the other components may also include other components used for various purposes depending on a type of electronic device 1000, or the like.

The electronic device 1000 may be a smartphone, a personal digital assistant (PDA), a digital video camera, a digital still camera, a network system, a computer, a monitor, a tablet PC, a laptop PC, a netbook PC, a television, a video game machine, a smartwatch, an automotive component, or the like. However, the electronic device 1000 is not limited thereto, and may be any other electronic device to process data.

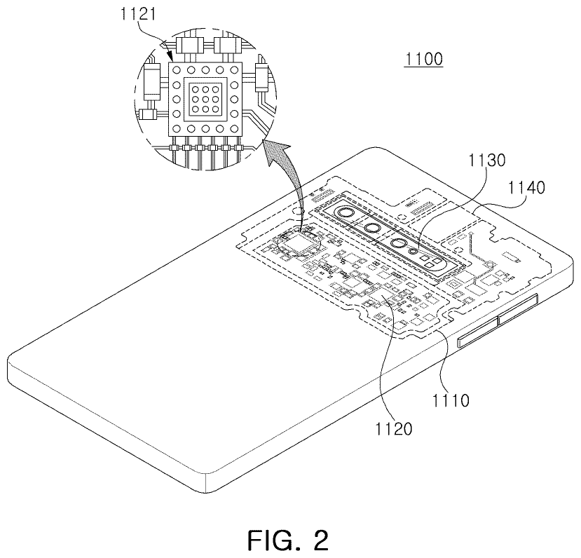

FIG. 2 is a schematic perspective view illustrating an example of an electronic device.

Referring to FIG. 2, an electronic device may be, for example, a smartphone 1100. The motherboard 1110 may be accommodated in the smartphone 1100, and various electronic components 1120 may be physically and/or electrically connected to the motherboard 1110. In addition, other electronic components that may or may not be physically and/or electrically connected to the motherboard 1110 may be accommodated therein, such as a camera module 1130 and/or a speaker 1140. A portion of the electronic components 1120 may be the above-described chip related components, for example, a component package 1121, but the present disclosure is not limited thereto. The component package 1121 may be in the form of a printed circuit board on which electronic components including active components and/or passive components are surface-mounted. The electronic device is not necessarily limited to the smartphone 1100, and may be other electronic devices as described above.

### Semiconductor Package Including Interposer

In general, a semiconductor chip may be integrated with numerous microscopic electric circuits, but may not serve as a finished semiconductor product by itself, and may be damaged by external physical or chemical impact. Accordingly, instead of using the semiconductor chip itself as it is, the semiconductor chip may be packaged, and may be used in an electronic device in a packaged state.

The reason why semiconductor packaging is required may be that there is a difference in circuit width between the semiconductor chip and a main board of an electronic device, in view of electrical connection. Specifically, in the case of the semiconductor chip, a size of a connection pad and a distance between connection pads may be significantly microscopic. Conversely, in the case of the main board used in the e electronic device, a size of a component mounting pad and a distance between component mounting pads may be significantly larger than a scale of the semiconductor chip. Accordingly, it may be difficult to directly mount the semiconductor chip on the main board, and packaging technology capable of buffering a difference in circuit width between the semiconductor chip and the main board may be required.

Hereinafter, a semiconductor package including an interposer manufactured by the packaging technology will be described in more detail with reference to the drawings.

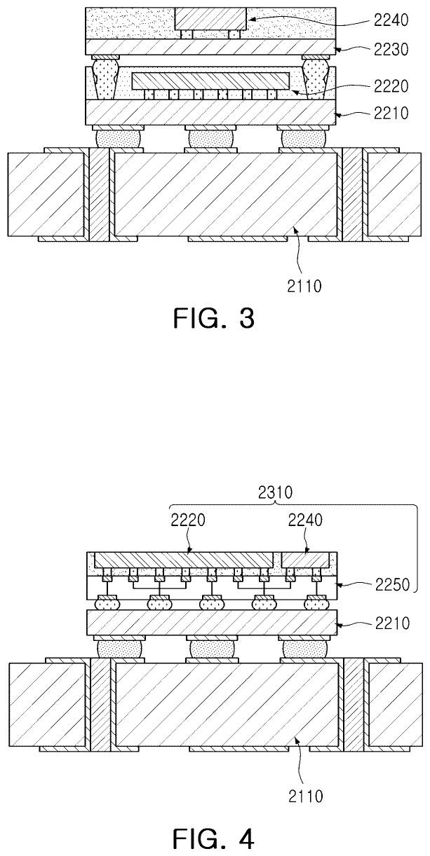

FIG. 3 is a schematic cross-sectional view illustrating a case in which a BGA package is mounted on a main board of an electronic device.

Among semiconductor chips, an application specific integrated circuit (ASIC), such as a graphics processing unit (GPU), may be high priced per chip, such that it may be highly important to perform packaging on the ASIC at a high yield. To this end, a ball grid array (BGA) substrate 2210 or the like capable of redistributing thousands to hundreds of thousands of connection pads may be first prepared before a semiconductor chip is mounted, and subsequently a high-priced semiconductor chip such as a GPU 2220 or the like may be mounted and packaged on the BGA substrate 2210 using surface mounting technology (SMT). Thereafter, the semiconductor chip may be finally mounted on a main board 2110.

In a case of the GPU 2220, it may be necessary to minimize a signal path between the GPU 2220 and a memory such as an HBM. To this end, a semiconductor chip such as an HBM 2240 may be mounted and then packaged on an interposer 2230, and may be then stacked on a package on which the GPU 2220 is mounted in the form of a package-on-package (POP). However, in this case, a thickness of a device may be excessively increased, and there is a limitation in minimizing the signal path.

FIG. 4 is a schematic cross-sectional view illustrating a case in which a silicon interposer package is mounted on a main board.

As a method for resolve the above-described issue, it may be considered to manufacture a semiconductor package 2310 including an organic interposer using organic interposer technology for surface-mounting, on a silicon interposer 2250, a first semiconductor chip such as a GPU 2220 and a second semiconductor chip such as an HBM 2240 in a side-by-side manner, and then performing packaging thereon. In this case, the GPU 2220 and the HBM 2240, having several thousands to several hundreds of thousands of connection pads, may be redistributed via the silicon interposer 2250, and may be electrically connected to each other via a shortest path. In addition, when the semiconductor package 2310 including the organic interposer is mounted again and redistributed on a BGA substrate 2210 or the like, the semiconductor package 2310 may be finally mounted on a main board 2110.

However, in the case of the silicon interposer 2250, it may be highly difficult to form a through-silicon via (TSV) or the like, and a cost required for manufacturing the silicon interposer 2250 is significantly high, such that it may be disadvantageous in terms of an increase in an area and a reduction in cost.

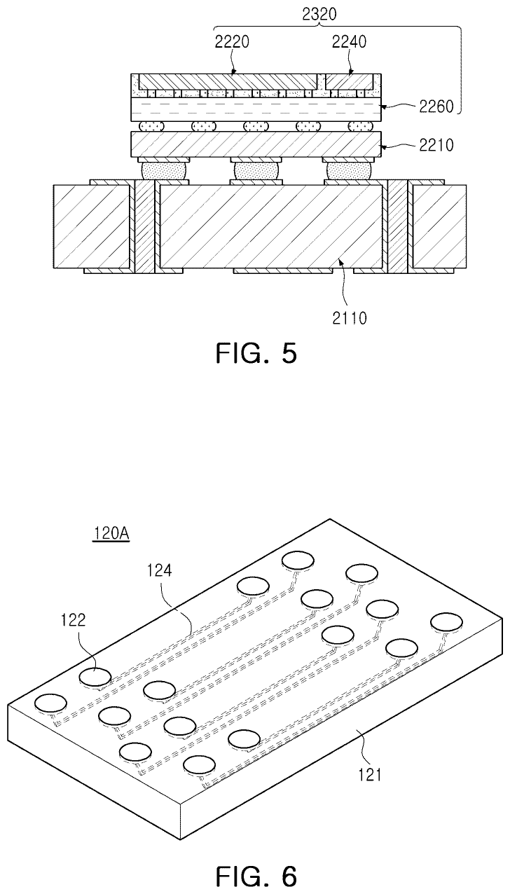

FIG. 5 is a schematic cross-sectional view illustrating a case in which an organic interposer package is mounted on a main board.

As a method for resolve the above-described issue, it may be considered to use an organic interposer 2260 instead of a silicon interposer 2250. For example, it may be considered to manufacture a semiconductor package 2320 including an organic interposing using organic interposer technology for surface-mounting, on the organic interposer 2260, a first semiconductor chip such as a GPU 2220 and a second semiconductor chip such as an HBM 2240 in a side-by-side manner, and then performing packaging thereon. In this case, the GPU 2220 and the HBM 2240, having several thousands to several hundreds of thousands of connection pads, may be redistributed via the organic interposer 2260, and may be electrically connected to each other via a shortest path. In addition, when the semiconductor package 2310 including the organic interposer is mounted again and redistributed on a BGA substrate 2210 or the like, the semiconductor package 2310 may be finally mounted on a main board 2110. In addition, it may be advantageous in terms of an increase in area and a reduction in cost.

However, in the case of using the organic interposer 2260, semiconductor chips 2220 and 2240 may need to be mounted on the organic interposer 2260 and then mounted on the BGA substrate 2210, such that a process may be slightly complicated, and a packaging yield may be reduced.

### Printed Circuit Board Including Interconnect Structure

FIG. 6 is a schematic perspective view illustrating an example of an interconnect structure.

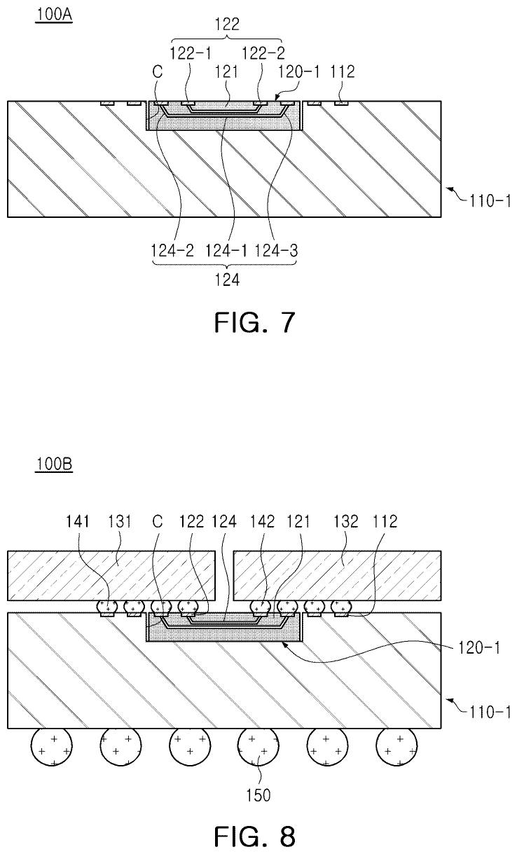

FIG. 7 is a schematic cross-sectional view illustrating an example of a printed circuit board.

Referring to FIG. 7, a printed circuit board 100A according to an example may include a substrate 110-1 and an interconnect structure 120-1 disposed on an upper side of the substrate 110-1. For example, the substrate 110-1 may have a cavity C passing through a portion of the substrate 110-1 from an upper surface thereof to a lower surface thereof, and the interconnect structure 120-1 may be disposed in the cavity C. The interconnect structure 120-1 may include an encapsulant 121, a plurality of second pads 122, and a plurality of metal wires 124. A plurality of first pads 112 may be embedded and disposed on the upper surface of the substrate 110-1, and the plurality of first pads 112 may be disposed to protrude on the upper surface of the substrate 110-1. A plurality of second pads 122 may be embedded and disposed on an upper surface of the encapsulant 121, and the plurality of second pads 122 may be disposed to protrude on the upper surface of the encapsulant 121. At least a portion of an upper surface of each of the plurality of first and second pads 112 and 122 may be exposed in an upward direction from the upper surface of each of the substrate 110-1 and the encapsulant 121. Accordingly, a plurality of semiconductor chips may be mounted and disposed on the plurality of first and second pads 112 and 122 and may be interconnected via the interconnect structure 120-1. In addition, as will be described below, the interconnect structure 120-1 may be manufactured using a relatively simple process, and may also be manufactured at low cost due to reduced material costs.

Hereinafter, components of the printed circuit board 100A according to an example will be described in more detail with reference to the drawings.

The substrate 110-1 may be an organic substrate or a silicon substrate, preferably an organic substrate. The organic substrate may be a core-type printed circuit board or a coreless-type printed circuit board, but the present disclosure is not limited thereto. The organic substrate may have various forms such as a rigid printed circuit board, a flexible printed circuit board, a rigid-flexible printed circuit board, and the like. The organic substrate may include a plurality of insulating layers, a plurality of interconnection layers disposed on or in the plurality of insulating layers, and a plurality of via layers respectively passing through the plurality of insulating layers. The organic substrate may further include a solder resist layer disposed on an outermost side of each of the plurality of insulating layers.

Each of the plurality of insulating layers may include an insulating material. The insulating material may include a thermosetting resin such as an epoxy resin, a thermoplastic resin such as polyimide, or a resin in which the thermosetting resin or the thermoplastic resin is impregnated in a material mixed with an inorganic filler such as silica, or a core material such as a glass fiber (or a glass cloth or a glass fabric), together with the inorganic filler, for example, copper clad laminate (CCL), Ajinomoto build-up film (ABF), prepreg, or the like, but the present disclosure is not limited thereto. The plurality of insulation layers may be distinguished from each other, or may not be distinguished, as necessary. For example, insulating layers, including substantially the same insulating material, may not be distinguished from each other, but insulating layers, including different insulating materials, may be more easily distinguished from each other. However, the present disclosure is not necessarily limited thereto, and the insulating layers may be clearly distinguished from each other regardless of the insulating material.

Each of the plurality of interconnection layers may include a metal material. The metal material may include copper (Cu), aluminum (Al), silver (Ag), tin (Sn), gold (Au), nickel (Ni), lead (Pb), titanium (Ti), or alloys thereof. Each of the plurality of interconnection layers may include an electroless plating layer (or chemical copper) and an electrolytic plating layer (or electrolytic copper). Each of the plurality of interconnection layers may further include copper foil, as necessary. Each of the plurality of interconnection layers may perform various functions depending on the design of a corresponding layer. For example, a ground pattern, a power pattern, a signal pattern, and the like may be included. Here, the signal pattern may include various signals other than the ground pattern, the power pattern, and the like, for example, a data signal. Each of the above-described patterns may include a line pattern, a plane pattern, and/or a pad pattern.

Each of the plurality of via layers may include a metal material. The metal material may include copper (Cu), aluminum (Al), silver (Ag), tin (Sn), gold (Au), nickel (Ni), lead (Pb), titanium (Ti), or alloys thereof. Each of the plurality of via layers may include an electroless plating layer (or chemical copper) and an electrolytic plating layer (or electrolytic copper). Each of the plurality of via layers may perform various functions according to the design of a corresponding layer. For example, a ground via, power via, signal via, and the like may be included. A via of each of the plurality of via layers may be a field type in which a via hole is filled with a metal material, but the present disclosure is not limited thereto, and may be a conformal type in which a metal material is disposed along a wall surface of the via hole. The via of each of the plurality of via layers may have various forms such as a cylinder, an hourglass, a taper, and the like.

The solder resist layer may protect internal components of the substrate 110-1. A material of the solder resist layer is not particularly limited. For example, an insulating material may be used. In this case, a solder resist may be used as the insulating material. However, the present disclosure is not limited thereto, and an ABF or the like may be used.

The plurality of first pads 112 may be disposed on the upper surface of the substrate 110-1, for example, embedded and disposed on the upper surface of the substrate 110-1, or disposed to protrude on the upper surface of the substrate 110-1. The plurality of first pads 112 may be semiconductor chip mounting pads. The plurality of first pads 112 may include a metal material such as copper (Cu), aluminum (Al), silver (Ag), tin (Sn), gold (Au), nickel (Ni), lead (Pb), titanium (Ti), or alloys thereof. The plurality of first pads 112 may include an electroless plating layer (or chemical copper) and an electrolytic plating layer (or electrolytic copper). The plurality of first pads 112 may further include copper foil, as necessary. The plurality of first pads 112 may include a ground pad, a power pad, a signal pad, and the like.

The interconnect structure 120-1 may be an interconnect between a plurality of semiconductor chips, for example, a bridge for a die-to-die interconnection. The interconnect structure 120-1 may include an encapsulant 121, a plurality of second pads 122 disposed on an upper surface of the encapsulant 121, and a plurality of metal wires 124 disposed in the encapsulant 121 and respectively connected to the plurality of second pads 122. The interconnect structure 120-1 may be disposed in the cavity C such that a lower surface of the encapsulant 121 is attached to a bottom surface of the cavity C of the substrate 110-1. The interconnect structure 120-1 may be attached using an adhesive or the like, as necessary.

The encapsulant 121 may provide an insulating body of the interconnect structure 120-1. The encapsulant 121 may protect the plurality of metal wires 124. The encapsulant 121 may include an insulating material, and may include, for example, a thermosetting resin such as an epoxy resin, a thermoplastic resin such as polyimide, or a material in which the thermosetting resin and the thermoplastic resin are mixed with an inorganic filler such as silica, but the present disclosure is not limited thereto. For example, an ABF, an epoxy molding compound (EMC), or the like may be used, but the present disclosure is not limited thereto.

The plurality of second pads 122 may be disposed on the upper surface of the encapsulant 121, for example, may be embedded and disposed on the upper surface of the encapsulant 121, or may be disposed to protrude on the upper surface of the encapsulant 121. The plurality of second pads 122 may be semiconductor chip mounting pads. The plurality of second pads 122 may include a metal material such as copper (Cu), aluminum (Al), silver (Ag), tin (Sn), gold (Au), nickel (Ni), lead (Pb), titanium (Ti), or alloys thereof. The plurality of second pads 122 may include an electroless plating layer (or chemical copper) and an electrolytic plating layer (or electrolytic copper). The plurality of second pads 122 may further include copper foil, as necessary. The plurality of second pads 122 may include a signal pad.

The plurality of metal wires 124 may be disposed in the encapsulant 121. The plurality of metal wires 124 may include a metal material, for example, copper (Cu), aluminum (Al), gold (Au), or the like. The plurality of metal wires 124 may preferably include gold (Au). In this case, for example, a gold wire may be used. The gold wire may have excellent current flow and may be chemically stable, and thus may be resistant to corrosion. In addition, the gold wire may have an appropriate hardness, such that a ball may be easily formed during first bonding, as necessary, and a semicircular loop may be appropriately formed during second bonding, as necessary. The plurality of metal wires 124 may be bent without a via, and thus may be in the form of a wire capable of net-to-net connection in various forms. For example, the plurality of metal wires 124 may include various types of metal wires used for wire bonding. The metal wires may, for example, consecutively have a predetermined length, and may be bent at at least one point, for example, a necessary position.

The plurality of metal wires 124 may be respectively connected to the plurality of second pads 122. For example, the plurality of metal wires 124 may include a first metal wire 124 connecting, to each other, at least two second pads 122-1 and 122-2 among the plurality of second pads 122. For example, the first metal wire 124 may include a first-first wire portion part 124-1 having a predetermined length in a horizontal direction, a first-second wire portion 124-2 extending from one end of the first-first wire portion 124-1, the first-second wire portion 124-2 connected to one 122-1 of the plurality of second pads 122, and a first-third wire portion 124-3 extending from the other end of the first-first wire portion 124-1, the first-third wire portion 124-3 connected to another one 122-2 of the plurality of second pads 122. The at least two second pads 122-1 and 122-2, among the plurality of second pads 122, connected to each other via the first metal wire 124 may be semiconductor chip mounting pads respectively connected to the first and second semiconductor chips. For example, at least one of the plurality of metal wires 124 may include a signal line interconnecting a plurality of semiconductor chips, for example, a signal line for a die-to-die interconnection.

FIG. 8 is a schematic cross-sectional view illustrating a modification of the printed circuit board of FIG. 7.

Referring to FIG. 8, as compared to the printed circuit board 100A according to another example, a printed circuit board 100B according to a modification may further include a first semiconductor chip 131 disposed on a substrate 110-1, the first semiconductor chip 131 connected to at least a portion of each of a plurality of first and second pads 112 and 122, and a second semiconductor chip 132 disposed on the substrate 110-1, the second semiconductor chip 132 connected to at least a portion of each of the plurality of first and second pads 112 and 122. The first and second semiconductor chips 131 and 132 may be connected to the plurality of first and second pads 112 and 122 via first and second connection members 141 and 142, respectively. A plurality of electrical connection metal members 150 may be further disposed on a lower side of the substrate 110-1, as necessary. For example, the printed circuit board 100B according to a modification may have a semiconductor package structure including the above-described printed circuit board 100A.

Each of the first and second semiconductor chips 131 and 132 may include an integrated circuit (IC) die in which hundreds to millions of devices or more are integrated into a single chip. In this case, the integrated circuit may be, for example, a logic chip such as a central processor (for example, CPU), a graphics processor (for example, GPU), a field programmable gate array (FPGA), a digital signal processor, a cryptographic processor, a microprocessor, a microcontroller, an application processor (for example, AP), an analog-to-digital converter, an application-specific IC (ASIC), or the like but the present disclosure is not limited thereto, and may be a memory chip such as a volatile memory (for example, DRAM), a nonvolatile memory (for example, ROM), a flash memory, an HBM, or the like, or another type of integrated circuit such as a power management IC (PMIC). For example, the first semiconductor chip 131 may include a logic chip such as a GPU, and the second semiconductor chips 132 and 133 may include a memory chip such as an HBM.

Each of the first and second semiconductor chips 131 and 132 may be formed based on an active wafer. In this case, silicon (Si), germanium (Ge), gallium arsenide (GaAs), and the like may be used as a base material included in each body. Various circuits may be formed in a body. A connection pad may be formed on each body, and the connection pad may include a conductive material such as aluminum (Al), copper (Cu), or the like. Each of the first and second semiconductor chips 131 and 132 may be bare dies. In this case, a metal bump may be disposed on the connection pad. Each of the first and second semiconductor chips 131 and 132 may be a packaged die. In this case, a redistribution layer may be further formed on the connection pad, and the metal bump may be disposed on the redistribution layer.

The first and second semiconductor chips 131 and 132 may be mounted on the substrate 110-1 and an interconnect structure 120-1 via the first and second connection members 141 and 142. The first and second connection members 141 and 142 may be formed of a low melting point metal, for example, solder such as tin (Sn)-aluminum (Al)-copper (Cu) or the like, but a material of each of the first and second connection members 141 and 142 is merely an example, and the material is not particularly limited thereto. Each of the first and second connection members 141 and 142 may be a ball or the like. Each of the first and second connection members 141 and 142 may be formed as a multilayer or a single layer. When formed as a multilayer, each of the first and second connection members 141 and 142 may include a copper pillar and solder. When formed as a single layer, each of the first and second connection members 141 and 142 may include tin-silver solder or copper, but the present disclosure is not limited thereto.

A plurality of electrical connection metal members 150 may be a component for connecting the printed circuit board 100B to a main board of an electronic device, other substrates, or the like. The plurality of electrical connection metal members 150 may be respectively connected to at least a portion of an interconnection layer of a lowermost layer of the substrate 110-1. The plurality of electrical connection metal members 150 may be respectively disposed via a plurality of under bump metals, as necessary. The plurality of electrical connection metal members 150 may be formed of a conductive material, for example, solder, but a material of each of the plurality of electrical connection metal members 150 is merely an example, and the material is not particularly limited thereto. Each of the plurality of electrical connection metal members 150 may be a ball, a pin, or the like. Each of the plurality of electrical connection metal members 150 may be formed as a multilayer or a single layer. When formed as a multilayer, each of the plurality of electrical connection metal members 150 may include a copper pillar and solder. When formed as a single layer, each of the plurality of electrical connection metal members 150 may include tin-silver solder or copper, but the present disclosure is not limited thereto.

Other descriptions may be the same as those of the printed circuit board 100A according to an example, and a repeated description thereof will be omitted.

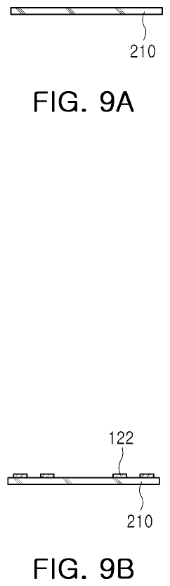

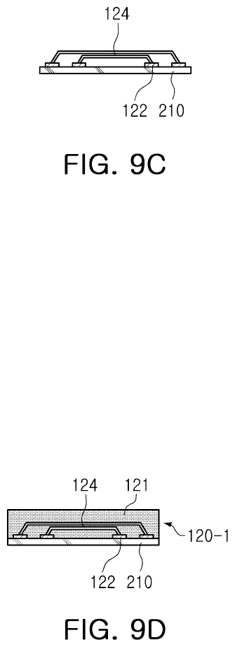

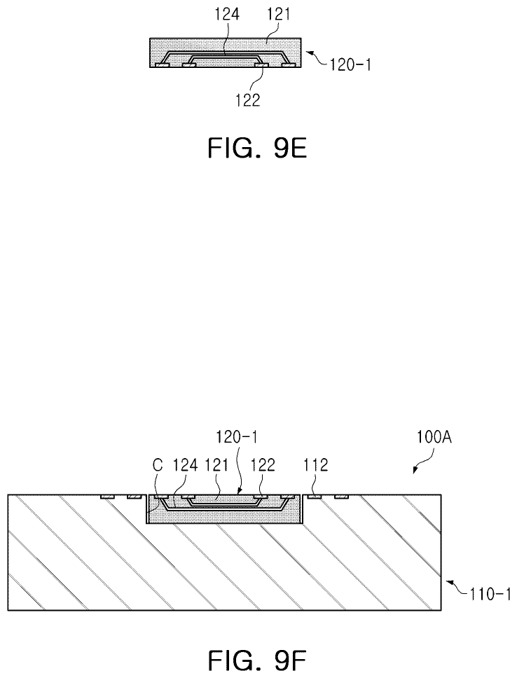

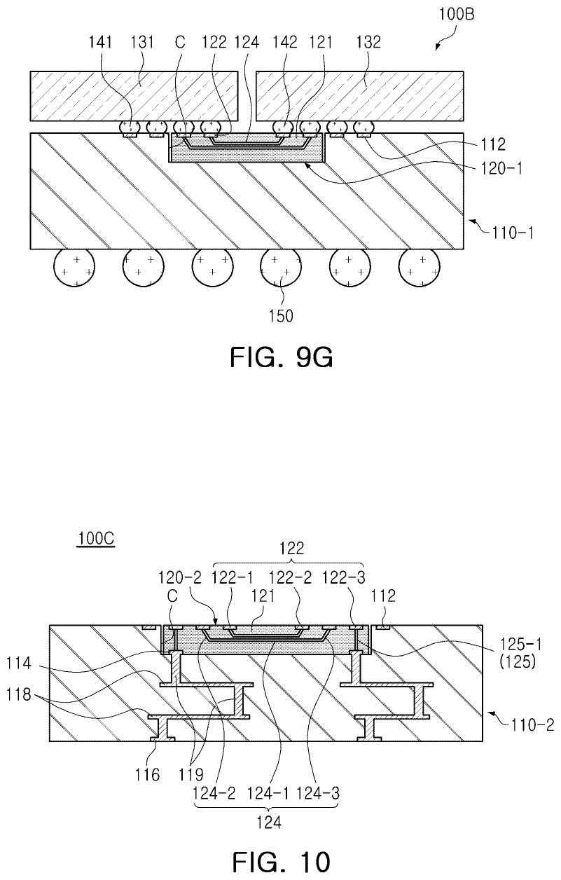

FIGS. 9A to 9G are schematic process diagrams illustrating an example of manufacturing the printed circuit board of FIGS. 7 and 8.

Referring to FIG. 9A, a carrier 210 may be prepared. The carrier 210 may be a glass carrier, but a material of the carrier 210 is not particularly limited to glass.

Referring to FIG. 9B, a plurality of second pads 122 may be formed on the carrier 210. The plurality of second pads 122 may be formed using a plating process. For example, the plurality of second pads 122 may be formed using a plating process using a semi additive process (SAP), modified SAP (MSAP), tenting (TT), or the like.

Referring to FIG. 9C, a plurality of metal wires 124, connected to the plurality of second pads 122, may be formed. The plurality of metal wires 124 may be formed using a wire bonding technique. For example, a gold wire bonding technique may be applied. In this case, since a build-up process may be unnecessary, thereby manufacturing at low cost due to reduced material costs. In addition, a manufacturing process may be simplified. In addition, a signal line for die-to-die interconnection may be implemented.

Referring to FIG. 9D, the plurality of second pads 122 and the plurality of metal wires 124 may be encapsulated using an encapsulant 121. Using such a relatively simple process, the above-described interconnect structure 120-1 may be manufactured on the carrier 210.

Referring to FIG. 9E, the carrier 210 may be removed. For example, the carrier 210 may be detached from the interconnect structure 120-1.

Referring to FIG. 9F, a substrate 110-1, having a cavity C, may be prepared, and the interconnect structure 120-1 may be disposed in the cavity C of the substrate 110-1. For example, the interconnect structure 120-1 may be attached to a bottom surface of the cavity C. More specifically, a back surface of the encapsulant 121 may be attached to the bottom surface of the cavity C. An adhesive may be used, as necessary. The printed circuit board 100A according to an example may be manufactured using a series of processes.

Referring to FIG. 9G, a first semiconductor chip 131 and a second semiconductor chip 132 may be mounted on the substrate 110-1 and the interconnect structure 120-1 such that the first semiconductor chip 131 and the second semiconductor chip 132 may be connected to the plurality of first and second pads 112 and 122 via first and second connection members 141 and 142, respectively.

In addition, the descriptions of the printed circuit board 100A according to an example and the printed circuit board 100B according to a modification may also be applicable to the example embodiment of FIGS. 9A to 9G, unless contradicted, and thus a repeated description thereof will be omitted.

FIG. 10 is a schematic cross-sectional view illustrating another example of a printed circuit board.

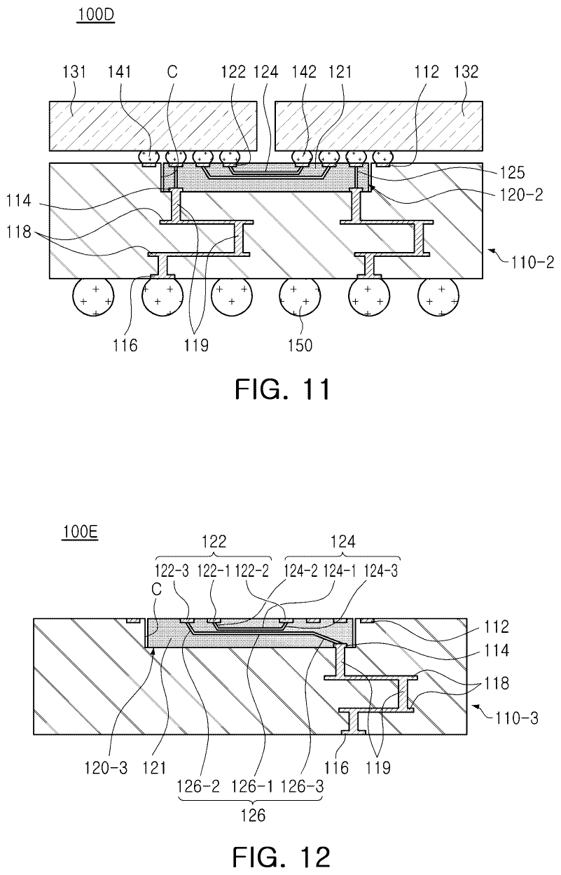

FIG. 11 is a schematic cross-sectional view illustrating a modification of the printed circuit board of FIG. 10.

Referring to FIGS. 10 and 11, as compared to the printed circuit board 100A according to an example and the printed circuit board 100B according to a modification thereof, in a printed circuit board 100C according to another example and a printed circuit board 100D according to a modification thereof, one or more third pads 114 may be further disposed on or in a substrate 110-2, for example, may be disposed on or in a bottom surface of a cavity C, and an interconnect structure 120-2 may be disposed on the one or more third pads 114. A plurality of metal wires 124 and 125 may further include a second metal wire 125, connecting at least one second pad 122-3, among a plurality of second pads 122, to at least one of the one or more third pads 114. The at least one second pad 122-3, connected to the second metal wire 125, may be a semiconductor chip mounting pad, connected to first and/or second semiconductor chips 131 and 132. The second metal wire 125 may include a second-first wire portion 125-1 having a predetermined length in a vertical direction, the second-first wire portion 125-1 having one end and the other end respectively connected to one 122-3 of the plurality of second pads 122 and one of the one or more third pads 114. A plurality of fourth pads 116 may be further disposed on a lower surface of the substrate 110-2, and one or more interconnection layers 118 and one or more via layers 119, connecting at least one of the one or more third pads 114 to at least one of the plurality of fourth pads 116, may be further disposed in the substrate 110-2. Thus, the interconnect structure 120-2 may have a modified form, and may be directly electrically connected to the substrate 110-2.

The one or more third pads 114 may be embedded in a lower side of the encapsulant 121, but the present disclosure is not limited thereto. For example, the encapsulant 121 may be attached onto the one or more third pads 114. That is, an arrangement relationship therebetween may be changed in various manners. In addition, a connection form between the one or more third pads 114 and the second metal wire 125 is not particularly limited. For example, the one or more third pads 114 and the second metal wire 125 may be directly connected to each other or connected to each other using a conductive adhesive. For example, the one or more third pads 114 and the second metal wire 125 may be connected in various forms.

The above description of the plurality of first pads 112 may be applicable to the detailed description of the one or more third pads 114 and the plurality of fourth pads 116. In addition, the above description of the plurality of interconnection layers and the plurality of via layers may be applicable to the detailed description of the one or more interconnection layers 118 and the one or more via layers 119.

Other descriptions may be substantially the same as those provided in connection with the printed circuit board 100A according to an example and the printed circuit board 100B according to a modification thereof, and thus a repeated description thereof will be omitted.

FIG. 12 is a schematic cross-sectional view illustrating another example of a printed circuit board.

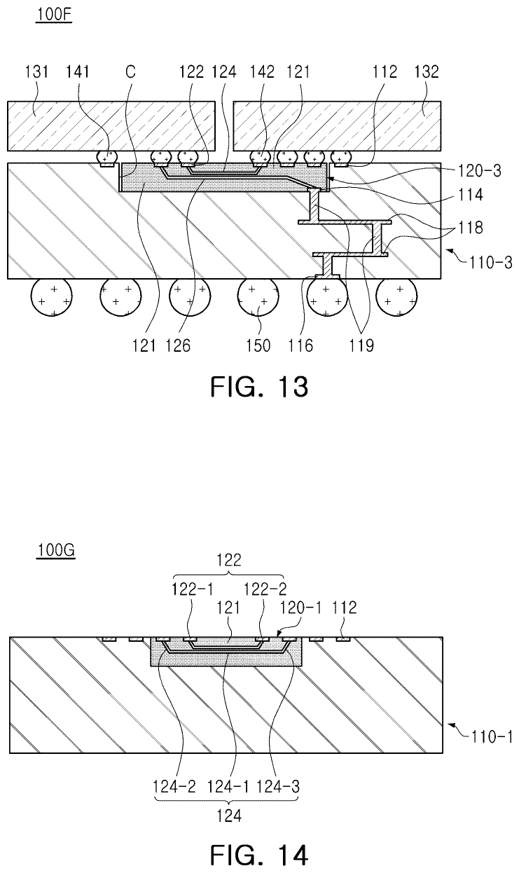

FIG. 13 is a schematic cross-sectional view illustrating a modification of the printed circuit board of FIG. 12.

Referring to FIGS. 12 and 13, as compared to the printed circuit board 100A according to an example and the printed circuit board 100B according to a modification thereof, in a printed circuit board 100E according to another example and a printed circuit board 100F according to a modification thereof, one or more third pads 114 may be further disposed on or in a substrate 110-3, for example, on or in a bottom surface of a cavity C, and an interconnect structure 120-3 may be disposed on the one or more third pads 114. A plurality of metal wires 124 and 126 may further include a third metal wire 126, connecting at least one second pad 122-3, among a plurality of second pads 122 to at least one of the one or more third pads 114. At least one second pad 122-3, connected to the third metal wire 126, may be a semiconductor chip mounting pad, connected to a first semiconductor chip 131. The third metal wire 126 may include a third-first wire portion 126-1 having a predetermined length in a horizontal direction, a third-second wire portion 126-2 extending from one end of the third-first wire portion 126-1, the third-second wire portion 126-2 connected to one 122-3 of the plurality of second pads 122, and a third-third wire portion 126-3 extending from the other end of the third-first wire portion 126-1, the third-third wire portion 126-3 connected to one of the one or more third pads 114. A plurality of fourth pads 116 may be further disposed on a lower surface of the substrate 110-3. One or more interconnection layers 118 and one or more via layers 119, connecting at least one of the one or more third pads 114 to at least one of the plurality of fourth pads 116, may be further disposed in the substrate 110-3. Thus, the interconnect structure 120-3 may have a modified form, and may be directly electrically connected to the substrate 110-3.

The one or more third pads 114 may be embedded in a lower side of the encapsulant 121, but the present disclosure is not limited thereto. For example, the encapsulant 121 may be attached onto the one or more third pads 114. That is, an arrangement relationship therebetween may be changed in various manners. In addition, a connection form between the one or more third pads 114 and the second metal wire 125 is not particularly limited. For example, the one or more third pads 114 and the second metal wire 125 may be directly connected to each other or connected to each other using a conductive adhesive. For example, the one or more third pads 114 and the second metal wire 125 may be connected in various forms.

The above description of the one or more third pads 114 and the plurality of fourth pads 116 may be applicable to the detailed description of the plurality of first pads 112. In addition, the above description of the plurality of interconnection layers and plurality of via layers may be applicable to the detailed description of the one or more interconnection layers 118 and the one or more via layers 119.

Other descriptions may be substantially the same as those provided in connection with the printed circuit board 100A according to an example and the printed circuit board 100B according to a modification thereof, and thus a repeated description thereof will be omitted.

FIG. 14 is a schematic cross-sectional view illustrating another example of a printed circuit board.

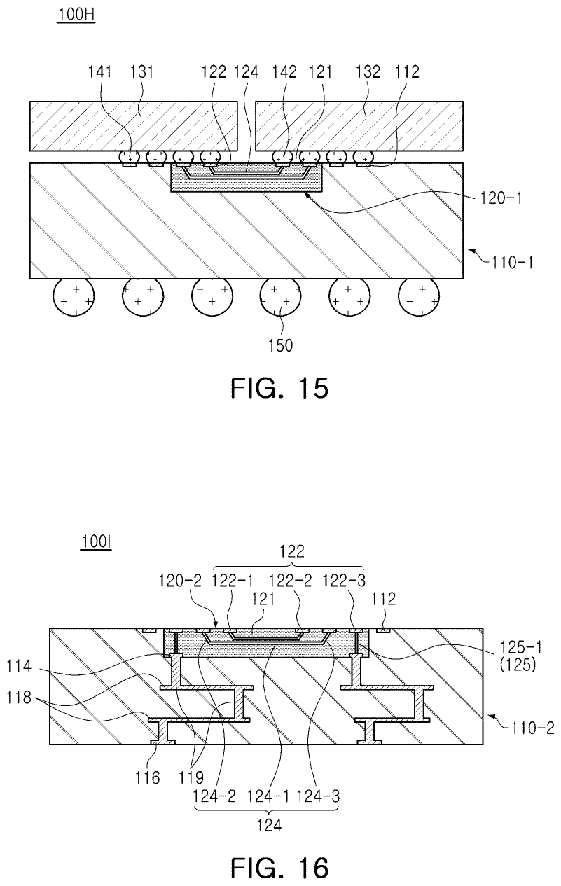

FIG. 15 is a schematic cross-sectional view illustrating a modification of the printed circuit board of FIG. 14.

Referring to FIGS. 14 and 15, as compared to the printed circuit board 100A according to an example and the printed circuit board 100B according to a modification thereof, in a printed circuit board 100G according to another example and a printed circuit board 100H according to a modification thereof, an interconnect structure 120-1 may be embedded and disposed on an upper side of a substrate 110-1 such that at least a portion of an upper surface of each of a plurality of second pads 122 is exposed from an upper surface of the substrate 110-1. For example, the interconnect structure 120-1 may be embedded and disposed on an outermost side of the substrate 110-1, and may be in contact with a side surface of the cavity C of the substrate 110-1.

Other descriptions may be substantially the same as those provided in connection with the printed circuit board 100A according to an example and the printed circuit board 100B according to a modification thereof, and thus a repeated description thereof will be omitted.

FIG. 16 is a schematic cross-sectional view illustrating another example of a printed circuit board.

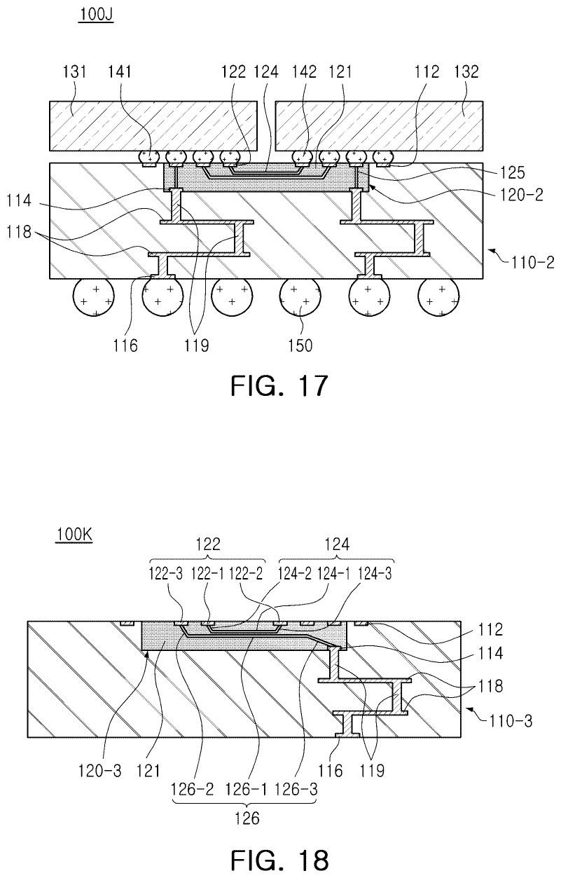

FIG. 17 is a schematic cross-sectional view illustrating a modification of the printed circuit board of FIG. 16.

Referring to FIGS. 16 and 17, as compared to the printed circuit board 100C according to another example and the printed circuit board 100D according to a modification thereof, in a printed circuit board 100I according to another example and a printed circuit board 100J according to a modification thereof, an interconnect structure 120-2 may be embedded and disposed on an upper side of a substrate 110-2 such that at least a portion of an upper surface of each of a plurality of second pads 122 is exposed from an upper surface of the substrate 110-2. For example, the interconnect structure 120-2 may be embedded and disposed on an outermost side of the substrate 110-2, and may be in contact with a side surface of the cavity C of the substrate 110-2.

Other descriptions may be substantially the same as those provided in connection with the printed circuit board 100C according to another example and the printed circuit board 100D according to a modification thereof, and thus a repeated description thereof will be omitted.

FIG. 18 is a schematic cross-sectional view illustrating another example of a printed circuit board.

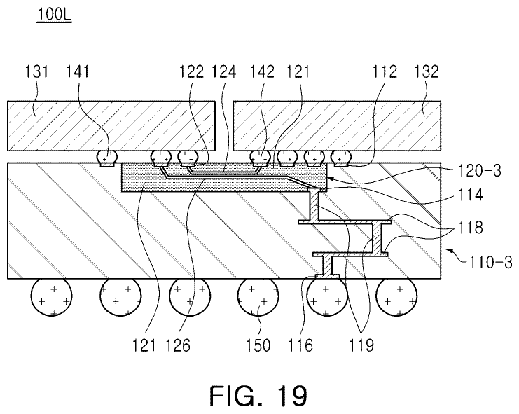

FIG. 19 is a schematic cross-sectional view illustrating a modification of the printed circuit board of FIG. 18.

Referring to FIGS. 18 and 19, as compare to the printed circuit board 100E according to another example and the printed circuit board 100F according to a modification thereof, in a printed circuit board 100K according to another example and a printed circuit board 100L according to a modification thereof, an interconnect structure 120-3 may be embedded and disposed on an upper side of a substrate 110-3 such that at least a portion of an upper surface of a plurality of second pads 122 is exposed from an upper surface of the substrate 110-3. For example, the interconnect structure 120-3 may be embedded and disposed on an outermost side of the substrate 110-3, and may be in contact with a side surface of the cavity C of the substrate 110-3.

Other descriptions may be substantially the same as those provided in connection with the printed circuit board 100E according to another example and the printed circuit board 100F according to a modification thereof, and thus a repeated description thereof will be omitted.

In the present disclosure, a cross-sectional shape may refer to a cross-sectional shape of an object when the object is vertically cut, or a cross-sectional shape of the object when the object is viewed in a side-view. In addition, a shape on a plane may be a shape of the object when the object is horizontally cut, or a planar shape of the object when the object is viewed in a top-view or a bottom-view.

In the present disclosure, an upper side, an upper portion, the upper surface, or the like is used to refer to a direction toward a surface on which an electronic component is mountable based on a cross-section of a drawing for ease, and a lower side, a lower portion, a lower surface, or the like is used to refer to an opposite direction thereof. However, the above-described directions are defined for ease of description. Thus, it should be understood that the scope of the claims is not particularly limited by the above-described directions.

As used herein, the term “connected” may not only refer to “directly connected” but also include “indirectly connected” by means of an adhesive layer, or the like. The term “electrically connected” may include both of a case in which components are “physically connected” and a case in which components are “not physically connected.” In addition, the terms “first,” “second,” and the like may be used to distinguish a component from another component, and may not limit a sequence and/or an importance, or others, in relation to the components. In some cases, a first component may be referred to as a second component, and similarly, a second component may be referred to as a first component without departing from the scope of the example embodiments.

As used herein, the term “an example embodiment” is provided to emphasize a particular feature, structure, or characteristic, and do not necessarily refer to the same example embodiment. In addition, the particular characteristics or features may be combined in any suitable manner in one or more example embodiments. For example, a context described in a specific example embodiment may be used in other example embodiments, even if it is not described in the other example embodiments, unless it is described contrary to or inconsistent with the context in the other example embodiments.

The terms used herein describe particular example embodiments only, and the present disclosure is not limited thereby. As used herein, singular forms “a,” “an,” and “the” are intended to include the plural forms as well, unless the context clearly indicates otherwise.

While example embodiments have been illustrated and described above, it will be apparent to those skilled in the art that modifications and variations could be made without departing from the scope of the present disclosure as defined by the appended claims.

What is claimed is:

1. A printed circuit board comprising:
a substrate having an upper surface at which a plurality of first pads are disposed; and
an interconnect structure including an encapsulant, a plurality of second pads disposed at an upper surface of the encapsulant, and a plurality of metal wires disposed in the encapsulant and respectively connected to at least one of the plurality of second pads, the interconnect structure disposed on an upper side of the substrate,
wherein at least a portion of an upper surface of each of the plurality of first and second pads is exposed in an upward direction from the upper surface of each of the substrate and the encapsulant.

2. The printed circuit substrate of claim 1, wherein the plurality of metal wires include a first metal wire connecting at least two second pads, among the plurality of second pads, to each other.

3. The printed circuit substrate of claim 2, wherein the at least two second pads, connected to each other via the first metal wire, are semiconductor chip mounting pads respectively connected to first and second semiconductor chips.

4. The printed circuit substrate of claim 2, wherein the first metal wire includes:
a first-first wire portion having a predetermined length in a horizontal direction;
a first-second wire portion extending from one end of the first-first wire portion and connected to one of the plurality of second pads; and
a first-third wire portion extending from the other end of the first-first wire portion and connected to another one of the plurality of second pads.

5. The printed circuit substrate of claim 2, wherein
one or more third pads are further disposed on or in the substrate, and
the interconnect structure is disposed on the one or more third pads.

6. The printed circuit substrate of claim 5, wherein the plurality of metal wires further include a second metal wire connecting at least one second pad, among the plurality of second pads, to at least one third pad, among the one or more third pads.

7. The printed circuit substrate of claim 6, wherein the at least one second pad, connected to the second metal wire, is a semiconductor chip mounting pad connected to at least one of first and second semiconductor chips.

8. The printed circuit substrate of claim 6, wherein the second metal wire includes a second-first wire portion having a predetermined length in a vertical direction, the second-first wire portion having one end and the other end respectively connected to one of the plurality of second pads and one of the one or more third pads.

9. The printed circuit substrate of claim 6, wherein the second metal wire includes:
a third-first wire portion having a predetermined length in a horizontal direction;
a third-second wire portion extending from one end of the third-first wire portion and connected to one of the plurality of second pads; and
a third-third wire portion extending from the other end of the third-first wire portion and connected to one of the one or more third pads.

10. The printed circuit substrate of claim 6, wherein
a plurality of fourth pads are further disposed on a lower surface of the substrate, and
one or more interconnection layers and one or more via layers, connecting at least one of the one or more third pads to at least one of the plurality of fourth pads, are further disposed in the substrate.

11. The printed circuit substrate of claim 1, wherein
the substrate has a cavity passing through a portion of the substrate from the upper surface of the substrate to a lower surface of the substrate, and
the interconnect structure is disposed in the cavity such that the other surface of the encapsulant is attached to a bottom surface of the cavity.

12. The printed circuit substrate of claim 11, wherein the interconnect structure is spaced apart from a side surface of the cavity.

13. The printed circuit substrate of claim 11, wherein the interconnect structure is in contact with a side surface of the cavity.

14. The printed circuit substrate of claim 1, wherein the interconnect structure is embedded and disposed on the upper side of the substrate such that at least a portion of the upper surface of each of the plurality of second pads is exposed from the upper surface of the substrate.

15. The printed circuit substrate of claim 1, further comprising:
a first semiconductor chip disposed on the substrate and connected to at least one or more of the plurality of first and second pads; and
a second semiconductor chip disposed on the substrate and connected to at least another one or more of the plurality of first and second pads.

16. The printed circuit substrate of claim 1, wherein the plurality of metal wires include gold (Au).

17. The printed circuit substrate of claim 1, wherein the plurality of metal wires are electrically insulated from each other within the interconnect structure.

18. A printed circuit substrate comprising:
a substrate; and
an interconnect structure disposed at an outermost side of the substrate, the interconnect structure including a plurality of metal wires,
wherein at least one of the plurality of metal wires includes a signal line interconnecting a plurality of semiconductor chips.

19. The printed circuit substrate of claim 18, further comprising:
the plurality of semiconductor chips disposed on the substrate.

20. The printed circuit substrate of claim 18, wherein the at least one metal wire consecutively has a predetermined length, and is bent at at least one point.
